(19) United States
(12) Patent Application Publication
(10) Pub. No.: US 2026/0362799 A1
(43) Pub. Date: Nov. 12, 2026

(54) FACET-DEPENDENT ADSORPTION FOR PLANARIZATION OF POLYCRYSTALLINE MATERIALS

(71) Applicant: Taiwan Semiconductor Manufacturing Co., Ltd., Hsinchu (TW)

(72) Inventors: Jin-Hao Jhang, Chubei City (TW); Chu-Hsuan Sha, Taipei City (TW); Shi-Ting Wu, Kaohsiung City (TW); Chih Hung Chen, Hsinchu (TW)

(21) Appl. No.: 19/748,892

(22) Filed: Jul. 21, 2026

Related U.S. Application Data
(63) Continuation of application No. 19/072,110, filed on Mar. 6, 2025.
(60) Provisional application No. 63/719,202, filed on Nov. 12, 2024.

(51) Int. Cl. H10D 84/85; H10D 30/00; H10D 30/01; H10D 30/43; H10D 30/67; H10D 62/10; H10D 84/01

(52) U.S. Cl. CPC H10D 84/851; H10D 30/014; H10D 30/0191; H10D 30/0321; H10D 30/43; H10D 30/502; H10D 30/6735; H10D 30/6745; H10D 62/121; H10D 84/0186

(57) ABSTRACT

A method of forming a semiconductor device includes: forming an electrically conductive feature over a substrate; forming a dielectric layer over the electrically conductive feature and the substrate; forming a layer of a polycrystalline material over the dielectric layer, where a first facet of the polycrystalline material and a second facet of the polycrystalline material have different lattice densities; selectively adsorbing molecules of a material on the first facet of the polycrystalline material; and after selectively adsorbing molecules of the material, performing a planarization process to the layer of the polycrystalline material, where the planarization process removes the polycrystalline material at a first removal rate at the first facet and removes the polycrystalline material at a second removal rate at the second facet, where the molecules of the material on the first facet cause a decrease in a difference between the first removal rate and the second removal rate.

### PRIORITY CLAIM AND CROSS-REFERENCE

This application is a continuation of Ser. No. 19/072,110, filed Mar. 6, 2025 and entitled “Facet-Dependent Adsorption for Planarization of Polycrystalline Materials,” which claims priority to U.S. Provisional Patent Application No. 63/719,202, filed Nov. 12, 2024, entitled “Facet-Dependent Chemical Adsorption to Enable Polycrystalline Materials Planarization,” which applications are hereby incorporated by reference in its entirety.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

Recently, vertically stacked transistor devices, such as complementary field-effect transistor (CFET) devices, provides a promising new architecture that achieves improved integration density by forming nanostructure field-effect transistors (NSFETs) that are vertically stacked over a substrate. Various aspects of this new architecture need to be studied and improved to achieve better device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A, 5B, 5C, 6A, 6B, 6C, 7A, 7B, 7C, 8A, 8B, 9A, 9B, 10A, 10B, 11A, 11B, 12A, and 12B illustrate cross-sectional views of a complementary field-effect transistor (CFET) device at various stages of manufacturing, in accordance with an embodiment.

FIGS. 13A and 13B illustrate cross-sectional views of a CFET device, in accordance with another embodiment.

FIG. 14 illustrates a zoomed-in view of a portion of a polycrystalline material, in an embodiment.

FIGS. 15, 16, and 17 illustrate various embodiment methods to planarize a polycrystalline material using facet-dependent adsorption, in some embodiments.

FIG. 18 illustrates a flow chart of a method of forming a semiconductor device, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

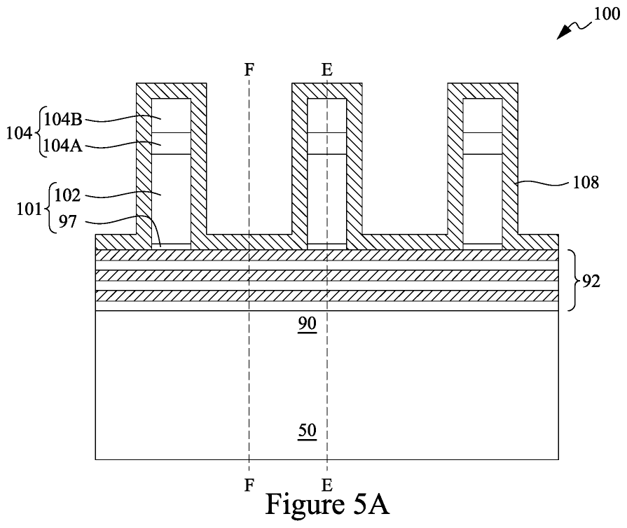

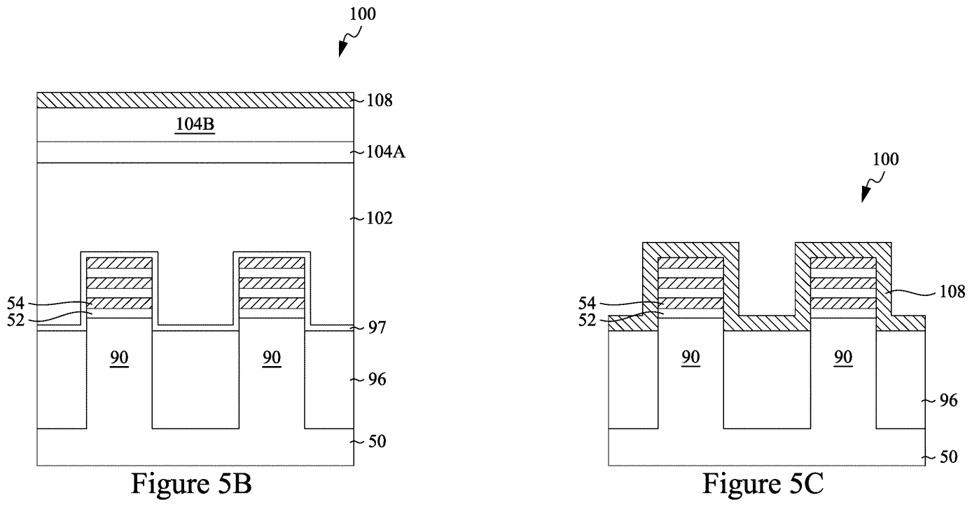

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise described, the same or similar reference numeral in different figures refer to the same or similar component formed by a same or similar formation process using a same or similar material(s). In addition, figures with the same numeral but different alphabets (e.g., FIG. 5A-5C) illustrate different views of the same device at the same stage of processing.

Various embodiments of the present disclosure are discussed in the context of forming a complementary field-effect transistor (CFET) device, with the understanding that the disclosed planarization methods using facet-dependent adsorption may be applied to other types of semiconductor devices, such as fin field-effect transistor (FinFET) devices, nanostructure field-effect transistor (NSFET) devices (e.g., nanowire devices, nanosheets devices), planar devices, or the like. In addition, the disclosed planarization methods are used for planarizing a polycrystalline material at a bonding interface as a non-limiting example, with the understanding that the disclosed planarization methods may be used for planarizing polycrystalline materials at other locations of a semiconductor device.

In some embodiments, a polycrystalline material with high thermal conductivity is used as the bonding material at the bonding interface of two semiconductor devices to improve the efficiency of heat dissipation. To overcome difficulties incurred by the polycrystalline material during a chemical mechanical planarization (CMP) process to planarize the polycrystalline material, facet-dependent adsorption is used to selectively form removal rate modification layer(s) on certain facets of the polycrystalline material. During the CMP process to planarize the surface of the polycrystalline material, the removal rate modification layer(s) increases the removal rate of the polycrystalline material at hard facets of the polycrystalline material, or decreases the removal rate of the polycrystalline material at soft facets of the polycrystalline material. By reducing the difference between the removal rates at the soft facets and the hard facets of the polycrystalline material, the removal rate modification layer allows the CMP process to successfully achieve increased planarity at the surface of the polycrystalline material.

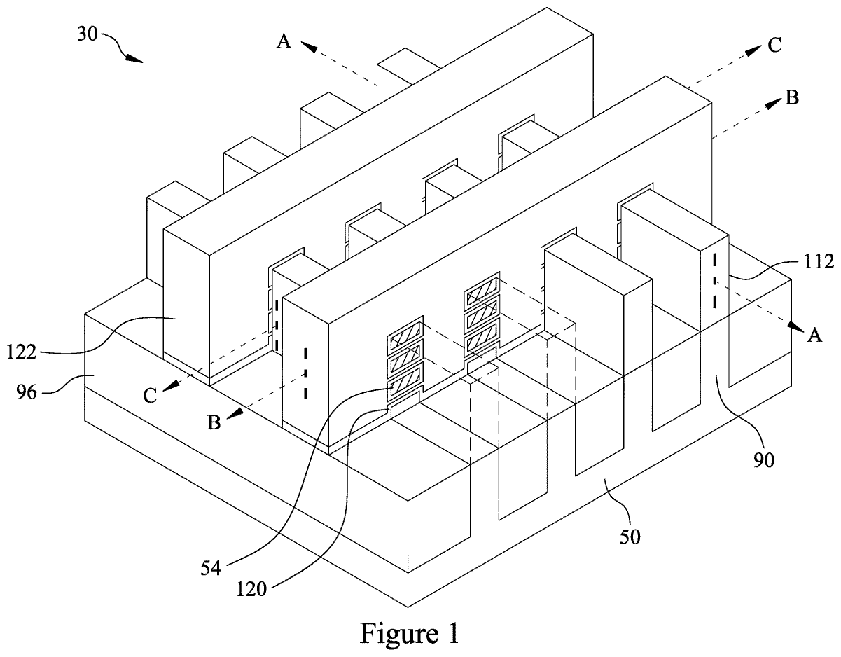

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the fin 90 and is in a direction of, for example, a current flow between the source/drain regions 112 of the NSFET device. Cross-section B-B is perpendicular to cross-section A-A and is along a longitudinal axis of the gate electrode 122. Cross-section C-C is parallel to cross-section B-B and extends through source/drain regions 112 of the NSFET device. Subsequent figures may refer to these reference cross-sections for clarity.

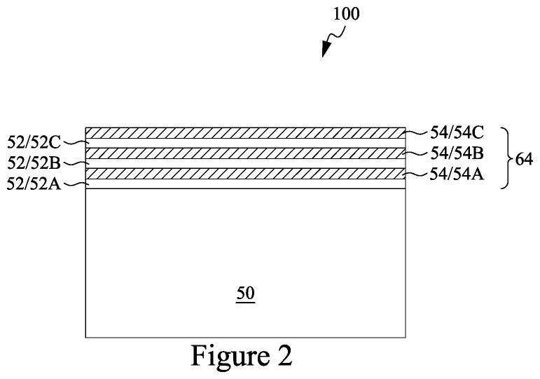

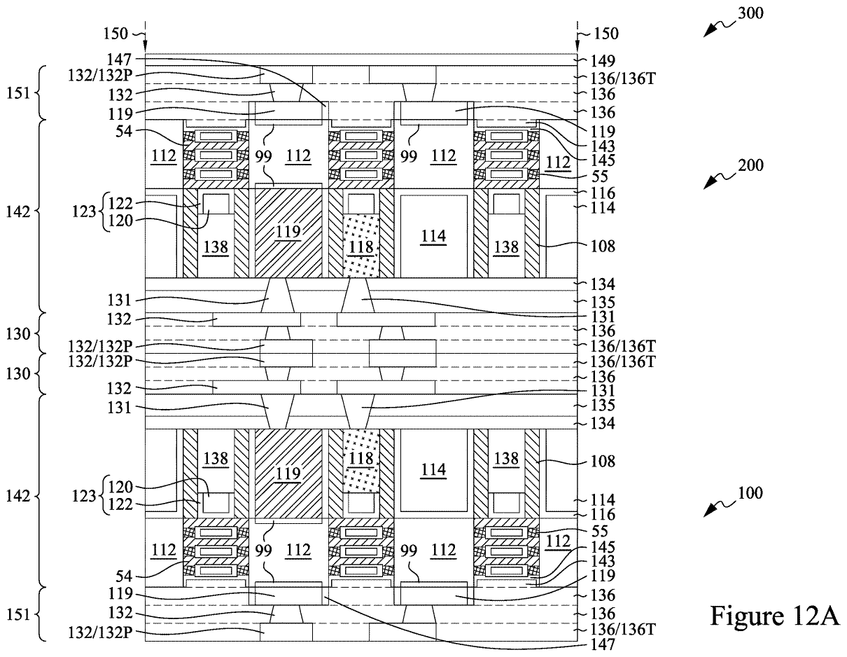

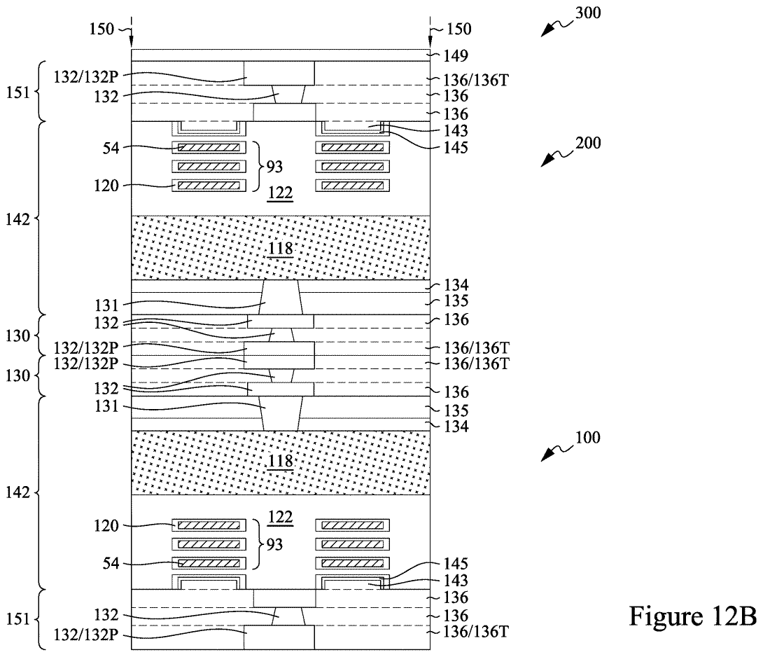

FIGS. 2, 3A, 3B, 4A, 4B, 5A, 5B, 5C, 6A, 6B, 6C, 7A, 7B, 7C, 8A, 8B, 9A, 9B, 10A, 10B, 11A, 11B, 12A, and 12B illustrate cross-sectional views of a complementary field-effect transistor (CFET) device 300 at various stages of manufacturing, in accordance with an embodiment. In particular, 2, 3A, 3B, 4A, 4B, 5A, 5B, 5C, 6A, 6B, 6C, 7A, 7B, 7C, 8A, 8B, 9A, 9B, 10A, 10B, 11A, and 11B illustrate cross-sectional views of an NSFET device 100 at various stages of processing, in an embodiment. The NSFET device 100 is then bonded to another NSFET device 200 to form the CFET device 300, as illustrated by the cross-sectional views of FIGS. 12A and 12B.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the second semiconductor materials illustrated in FIG. 2 are merely non-limiting examples. Other numbers of layers are also possible and are fully intended to be included within the scope of the present disclosure.

In some embodiments, the first semiconductor material 52 is an epitaxial material appropriate for forming channel regions of p-type FETs, such as silicon germanium (SiₓGe₁₋ₓ, where x can be in the range of 0 to 1), and the second semiconductor material 54 is an epitaxial material appropriate for forming channel regions of n-type FETs, such as silicon. In some embodiments, the second semiconductor material 54 (e.g., silicon) may be used to form both n-type or p-type FETs, and the first semiconductor material 52 is used as a sacrificial material that is removed later. The multi-layer stack 64 (which may also be referred to as an epitaxial material stack) will be patterned to form channel regions of an NSFET in subsequent processing. For example, the multi-layer stack 64 may be patterned and etched to form nanostructures (e.g., nanosheets or nanowires), with the channel regions of the resulting NSFET including nanostructures that are vertically stacked over a fin, and with each nanostructure extending parallel to a major upper surface of the substrate.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed.

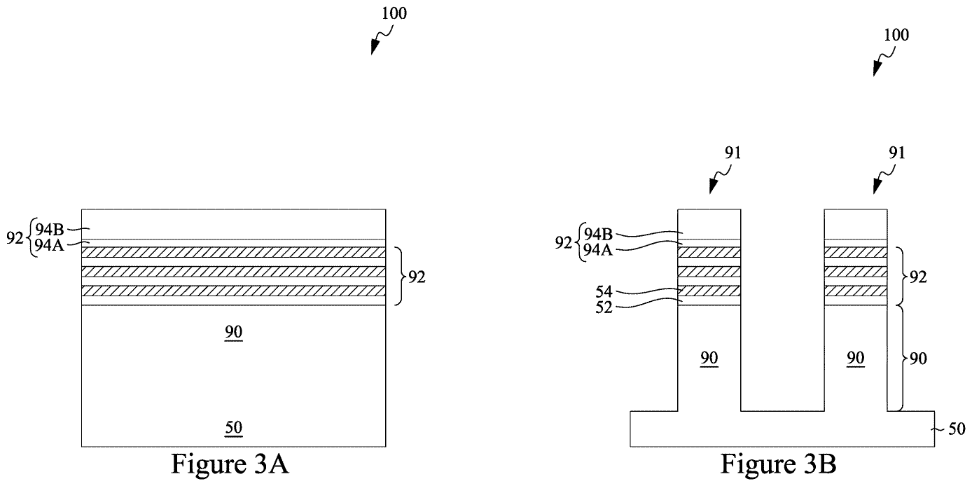

FIGS. 3A, 3B, 4A, 4B, 5A, 5B, 5C, 6A, 6B, 6C, 7A, 7B, 7C, 8A, 8B, 9A, 9B, 10A, 10B, 11A, and 11B illustrate cross-sectional views of the NSFET device 100 at subsequent stages of manufacturing, in accordance with an embodiment. FIGS. 3A, 4A, 5A, 6A, 7A, 8A, 9A, 10A, and 11A are cross-sectional views along cross-section A-A in FIG. 1. FIGS. 3B, 4B, 5B, 6B, 7B, 8B, 9B, 10B, and 11B are cross-sectional views along cross-section B-B in FIG. 1. FIGS. 5C, 6C, and 7C are cross-sectional views along cross-section C-C in FIG. 1. The number of fins and the number of gate structures illustrated in the figures are merely non-limiting examples, it should be appreciated that other numbers of fins and other numbers of gate structures may also be formed.

In FIGS. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. In an embodiment, a sacrificial layer is formed over a substrate and patterned using a photolithography process. Spacers are formed alongside the patterned sacrificial layer using a self-aligned process. The sacrificial layer is then removed, and the remaining spacers are then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etch process, such as a reactive ion etch (RIE), neutral beam etch (NBE), the like, or a combination thereof. The etching is an anisotropic etching process, in some embodiments. After the etching process, the patterned multi-layer stack 64 forms the layer stacks 92, and the patterned portion of the substrate 50 forms the fins 90, as illustrated in FIGS. 3A and 3B. The unetched lower portion of the substrate 50 is referred to as substrate 50 in FIGS. 3A and 3B (and subsequent figures). Therefore, in the illustrated embodiment, the layer stack 92 also includes alternating layers of the first semiconductor material 52 and the second semiconductor material 54, and the fin 90 is formed of a same material (e.g., silicon) as the substrate 50.

The fins 90 and the layer stacks 92 in FIG. 3B are illustrated to have substantially perpendicular sidewalls (e.g. perpendicular to the major upper surface of the substrate 50). The shapes of the fins 90 and the layer stacks 92 illustrated in FIG. 3B are merely non-limiting examples. The fins 90 and the layer stacks 92 may have sloped sidewalls (e.g., having trapezoidal cross-sections). The sloped sidewalls may be formed due to the properties of the anisotropic etching process used to form the fins 90 and the layer stacks 92. For example, the etching capability of the anisotropic etching process may decrease along the downward vertical direction of FIG. 3B, which may result in the sloped sidewalls for the fins 90 and the layer stacks 92.

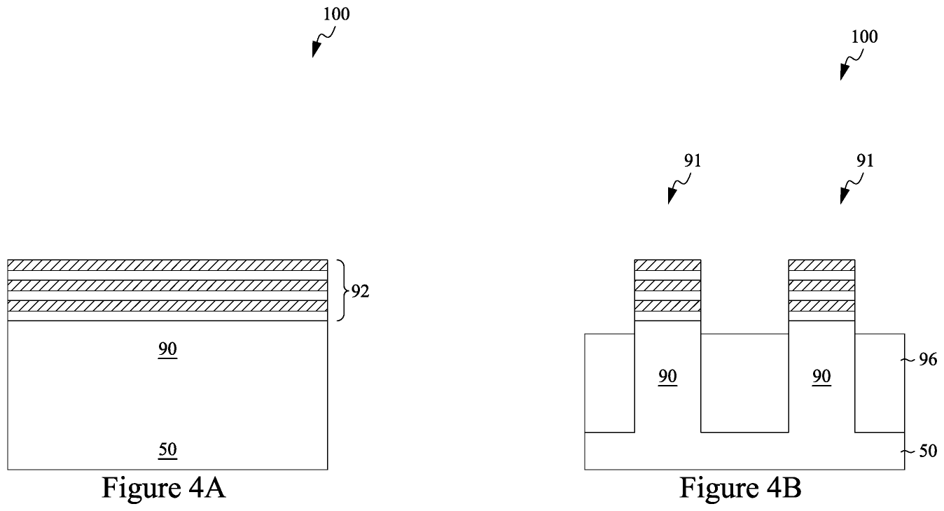

Next, in FIGS. 4A and 4B, shallow trench isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material over the fin structures 91. The removal process also removes the mask 94, in the illustrated embodiment. In some embodiments, a planarization process such as a chemical mechanical planarization (CMP) process, an etch back process, combinations thereof, or the like, may be utilized. The planarization process exposes the layer stacks 92 such that top surfaces of the layer stacks 92 and the insulation material are level after the planarization process is completed. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than other materials, such as the materials of the fin 90 and the layer stack 92). For example, a chemical oxide removal with a suitable etchant such as dilute hydrofluoric (dHF) acid may be used.

Next, in FIGS. 5A-5C, a dummy dielectric layer 97 is formed over the layer stack 92 and over the STI regions 96. The dummy dielectric layer 97 may be, for example, silicon oxide, silicon nitride, a combination thereof, or the like, and may be deposited or thermally grown according to acceptable techniques.

Next, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by CMP. The dummy gate layer may be a conductive material and may be selected from a group including amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art. The dummy gate layer may be made of other materials that have a high etching selectivity from the STI regions 96.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectrics 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. The dummy gates 102 and the dummy gate dielectrics 97 are collectively referred to as dummy gate structures 101.

Next, a gate spacer layer 108 is formed by conformally depositing an insulating material over the layer stacks 92, the STI regions 96, and the dummy gates 102. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

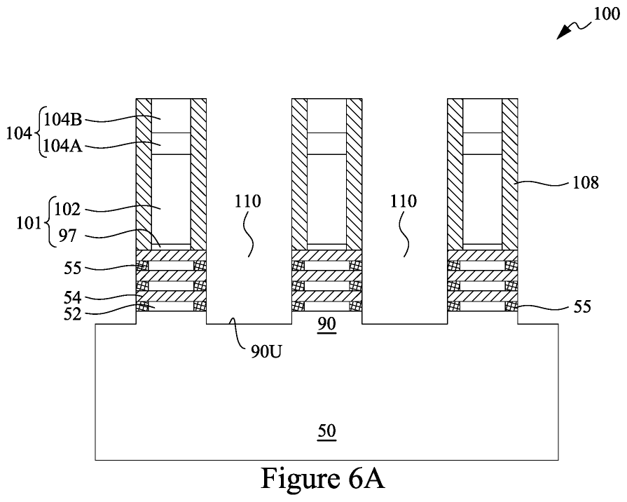

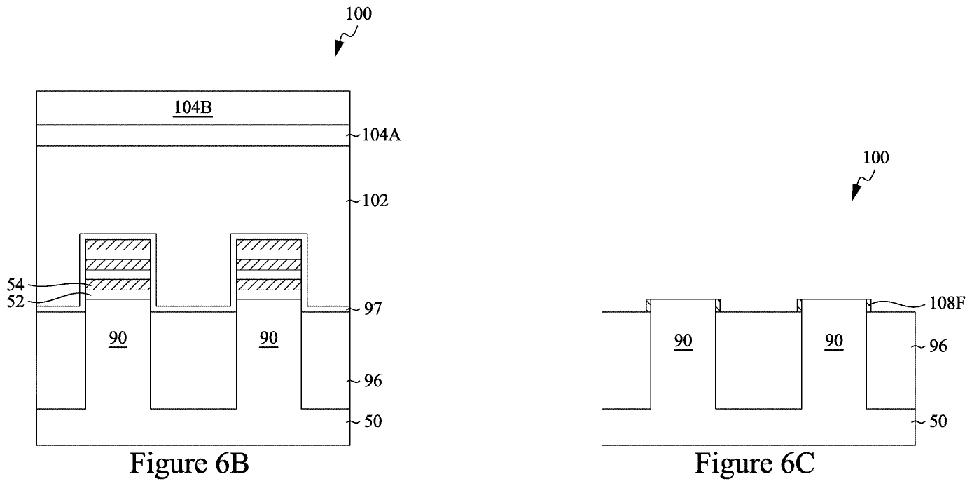

FIGS. 5B and 5C illustrate cross-sectional views of the NSFET device 100 in FIG. 5A along cross-sections E-E and F-F in FIG. 5A, respectively. The cross-sections E-E and F-F correspond to cross-sections B-B and C-C in FIG. 1, respectively. Unless otherwise specified, subsequent figures with alphabets A, B and C (e.g., FIGS. 6A, 6B, and 6C) illustrate cross-sectional views along the same cross-sections as FIGS. 5A, 5B, and 5C, respectively.

Next, in FIGS. 6A-6C, the gate spacer layer 108 is etched by an anisotropic etching process to form gate spacers 108. The anisotropic etching process may remove horizontal portions of the gate spacer layer 108 (e.g., portions over the STI regions 96 and the dummy gates structures 101), with remaining vertical portions of the gate spacer layer 108 (e.g., portions along sidewalls of the dummy gate structures 101) forming the gate spacers 108.

After the formation of the gate spacers 108, implantation for lightly doped source/drain (LDD) regions (not shown) may be performed. Appropriate type (e.g., p-type or n-type) impurities may be implanted into the exposed layer stacks 92 and/or fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities between about 1E15/cm³ and about 1E16/cm³. An anneal process may be used to activate the implanted impurities.

Next, openings 110 (which may also be referred to as recesses, or source/drain openings) are formed in the layer stacks 92. The openings 110 may extend through the layer stacks 92 and into the fins 90. The openings 110 may be formed by an anisotropic etching process using, e.g., the dummy gate structures 101 and the gate spacers 108 as an etching mask.

After the openings 110 are formed, a selective etching process is performed to recess end portions of the first semiconductor material 52 exposed by the openings 110 without substantially attacking the second semiconductor material 54. After the selective etching process, recesses (also referred to as sidewall recesses) are formed in the first semiconductor material 52 at locations where the removed end portions used to be.

Next, an inner spacer layer is formed (e.g., conformally) in the openings 110 to line sidewalls and bottoms of the openings 110. The inner spacer layer also fills the sidewall recesses of the first semiconductor material 52 formed by the previous selective etching process. The inner spacer layer may be a suitable dielectric material, such as silicon carbonitride (SiCN), silicon oxycarbonitride (SiOCN), or the like, and may be formed by a suitable deposition method such as PVD, CVD, atomic layer deposition (ALD), or the like. Next, an etching process, such as an anisotropic etching process, is performed to remove portions of the inner spacer layer disposed outside the sidewall recesses of the first semiconductor material 52. The remaining portions of the inner spacer layer (e.g., portions disposed inside the sidewall recesses of the first semiconductor material 52) form inner spacers 55. As illustrated in FIG. 6A, the openings 110 expose sidewalls of the second semiconductor material 54, and expose upper surfaces 90U of the fins 90 at the bottoms of the openings 110.

In the example of FIG. 6C, portions of the gate spacer layer 108 disposed on the upper surface of the STI regions 96 between neighboring fins 90 are completely removed by the anisotropic etching process used for forming the gate spacers 108. Remaining portions of the gate spacer layer 108 along the sidewalls of the fins 90 form fin spacers 108F. In FIG. 6C, the upper surface of the STI regions 96 between neighboring fins 90 is illustrated as a flat surface as a non-limiting example. The upper surface of the STI regions 96 between neighboring fins 90 may be curved (e.g., concave), e.g., due to the anisotropic etching process removing upper portions of the STI regions 96.

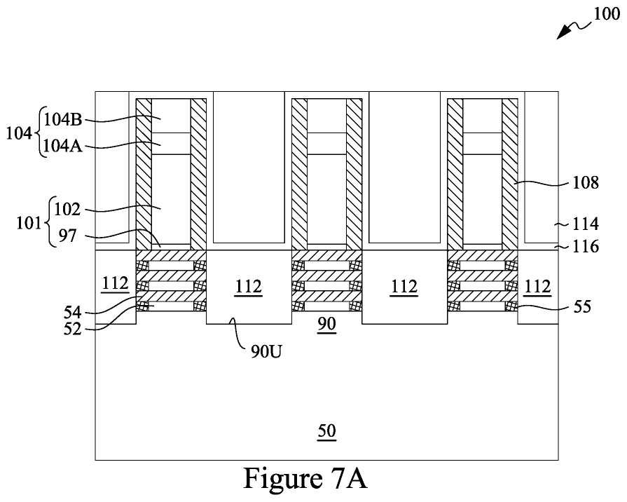

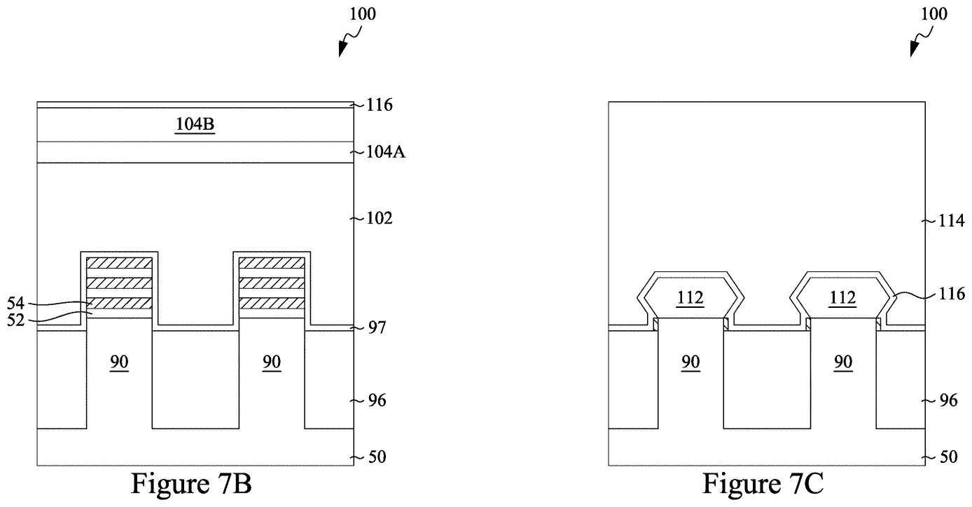

Next, in FIG. 7A-7C, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed replacement gate structures of the resulting NSFET device.

The epitaxial source/drain regions 112 are epitaxially grown in the openings 110, in some embodiments. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with a dopant (e.g., n-type impurities or p-type impurities), similar to the process previously discussed for forming lightly-doped source/drain regions, followed by an anneal. The source/drain regions may have an impurity concentration (may also be referred to as a dopant concentration) of between about 1E19/cm³ and about 1E21/cm³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In the illustrated embodiment, adjacent epitaxial source/drain regions 112 remain separated (see FIG. 7C) after the epitaxy process is completed. In other embodiments, these facets cause adjacent epitaxial source/drain regions 112 to merge together.

Next, a contact etch stop layer (CESL) 116 is formed (e.g., conformally) over the source/drain regions 112 and over the dummy gate structures 101, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, PECVD, or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may be used.

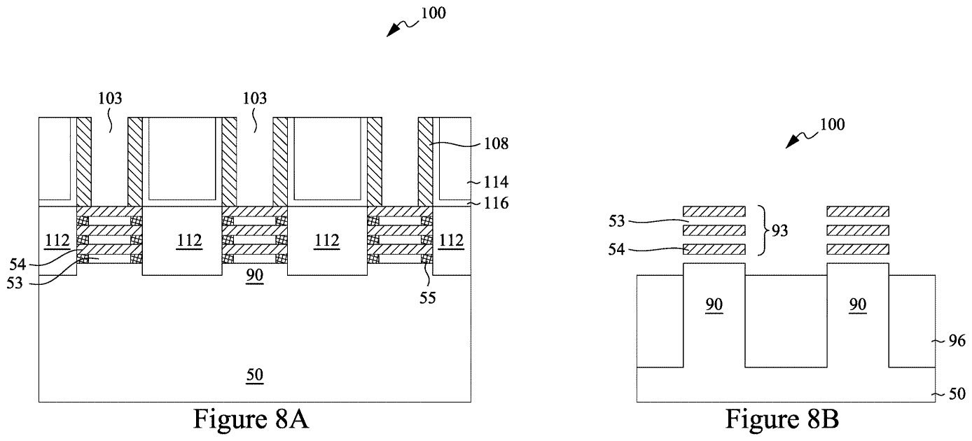

Next, in FIGS. 8A and 8B, the dummy gates 102 and the dummy gate dielectrics 97 are removed. Note that for simplicity, the cross-sectional views along cross-section F-F illustrated in FIG. 5A are not illustrated for processing steps hereinafter, because such cross-sectional views are the same as or similar to FIG. 7C, or may be easily modified from FIG. 7C (e.g., by adding additional layers formed over the first ILD 114).

To remove the dummy gates 102, a planarization process, such as a CMP, is performed to level the top surfaces of the first ILD 114 and the CESL 116 with the top surfaces of the dummy gates 102 and the gate spacers 108. The planarization process may also remove the masks 104 (see FIG. 7A) on the dummy gates 102, and portions of the gate spacers 108 along sidewalls of the masks 104. After the planarization process, top surfaces of the dummy gates 102, the gate spacers 108, the CESL 116, and the first ILD 114 are level. Accordingly, the top surfaces of the dummy gates 102 are exposed through the first ILD 114.

Next, the dummy gates 102 are removed in an etching step(s), so that recesses 103 (also referred to as gate trenches) are formed. In some embodiments, the dummy gates 102 are removed by an anisotropic dry etch process. For example, the etching process may include a dry etch process using reaction gas(es) that selectively etch the dummy gates 102 without etching the first ILD 114 or the gate spacers 108. During the removal of the dummy gates 102, the dummy gate dielectrics 97 may be used as an etch stop layer when the dummy gates 102 are etched. The dummy gate dielectrics 97 may then be removed after the removal of the dummy gates 102. An etching process, such as an isotropic etching process, may be performed to remove the dummy gate dielectrics 97. As illustrated in FIGS. 8A and 8B, the recesses 103 expose the channel regions of the NSFET device 100. The channel regions are disposed between neighboring pairs of the epitaxial source/drain regions 112.

Next, the first semiconductor material 52 (e.g., portions exposed by the recesses 103) is removed to release the second semiconductor material 54. After the first semiconductor material 52 is removed, the second semiconductor material 54 (e.g., portions underlying the dummy gates 102 before the dummy gates 102 are removed) forms a plurality of nanostructures 54. The nanostructures 54 may be collectively referred to as the channel regions 93 or the channel layers 93 of the NSFET device 100 formed. As illustrated in FIGS. 8A and 8B, gaps 53 (e.g., empty spaces) are formed between the nanostructures 54 by the removal of the first semiconductor material 52. In some embodiments, the nanostructures 54 are nanosheets or nanowires, depending on, e.g., the dimensions (e.g., size and/or aspect ratio) of the nanostructures 54.

In some embodiments, the first semiconductor material 52 is removed by a selective etching process using an etchant that is selective to (e.g., having a higher etch rate for) the first semiconductor material 52, such that the first semiconductor material 52 is removed without substantially attacking the second semiconductor material 54. In some embodiments, an isotropic etching process is performed to remove the first semiconductor material 52. The isotropic etching process is performed using an etching gas, and optionally, a carrier gas. The etching gas comprises F₂ and HF, and the carrier gas may be an inert gas such as Ar, He, N₂, combinations thereof, or the like, in some embodiments.

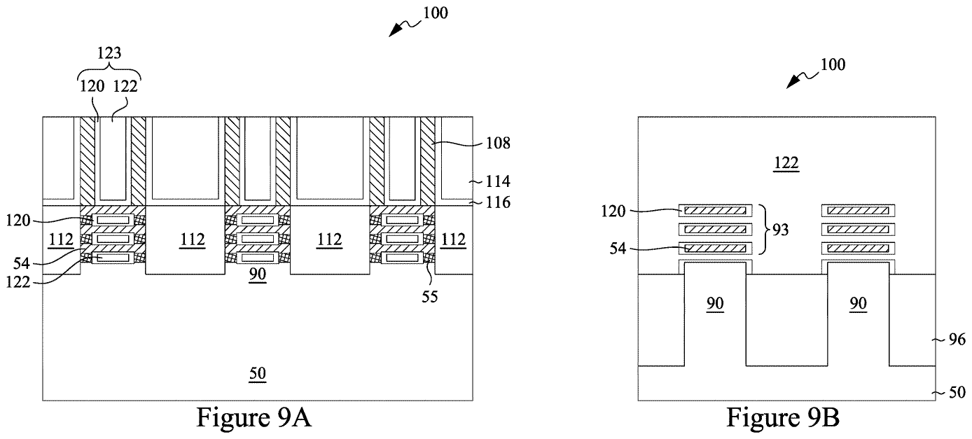

Next, in FIGS. 9A and 9B, a gate dielectric material 120 and a gate electrode material 122 are formed in the recesses 103 to form replacement gate structures 123. The gate dielectric material 120 is deposited conformally in the recesses 103, such as on the top surfaces and the sidewalls of the semiconductor fins 90, and on sidewalls of the gate spacers 108. The gate dielectric material 120 may also be formed on the top surface of the first ILD 114. Notably, the gate dielectric material 120 is formed to wrap around the nanostructures 54. In accordance with some embodiments, the gate dielectric material 120 comprises silicon oxide, silicon nitride, or multilayers thereof. In some embodiments, the gate dielectric material 120 is formed of a high-K dielectric material, and in these embodiments, the gate dielectric material 120 may have a dielectric constant (also referred to as K value) greater than about 7.0, and may include a metal oxide or a silicate of Hf, Al, Zr, La, Mg, Ba, Ti, or Pb, or combinations thereof. The formation methods of the gate dielectric material 120 may include Molecular-Beam Deposition (MBD), ALD, PECVD, and the like.

Next, the gate electrode material 122 is deposited over and around the gate dielectric material 120, and fills the remaining portions of the recesses 103. The gate electrode material 122 may include a metal-containing material such as TiN, TiO, TaN, TaC, Co, Ru, Al, W, combinations thereof, or multi-layers thereof. For example, although a single-layer gate electrode material 122 is illustrated, the gate electrode material 122 may comprise any number of liner layers (e.g., barrier layers), any number of work function tuning layers, and a fill material (e.g., a fill metal, an electrically conductive material). After the gate electrode material 122 is formed, a planarization process, such as a CMP, may be performed to remove excess portions of the gate dielectric material 120 and the gate electrode material 122, which excess portions are over the top surface of the first ILD 114. The remaining portions of the gate electrode material 122 and the gate dielectric material 120 thus form the gate electrodes 122 and the gate dielectric layers 120 of the replacement gate structures 123 of the resulting NSFET device 100, respectively. Each gate electrode 122 and the corresponding gate dielectric layer 120 may be collectively referred to as a gate stack, a replacement gate structure, a metal gate structure, or a gate structure. Each gate structure 123 extends around the respective nanostructures 54.

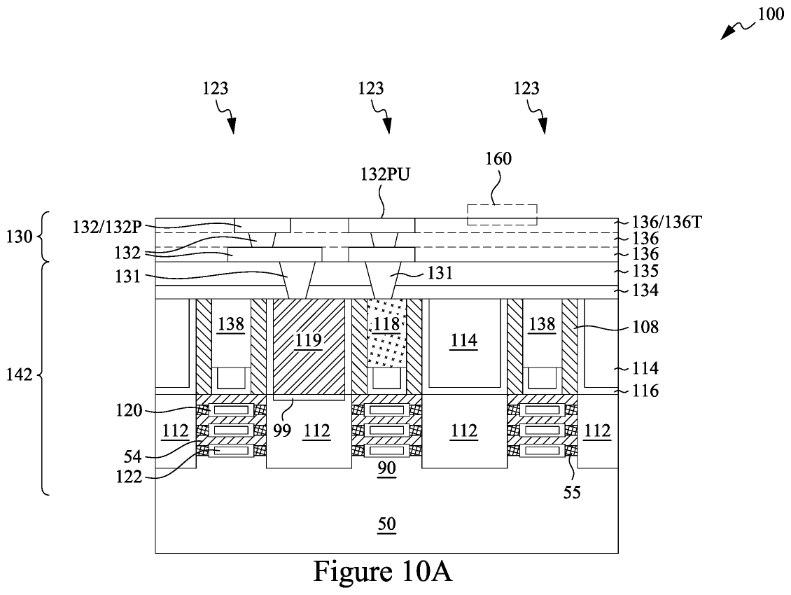

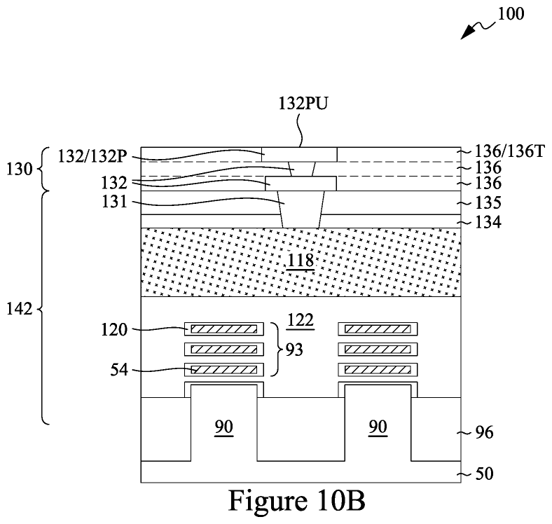

Next, in FIGS. 10A and 10B, gate masks 138 are formed over the replacement gate structures 123. The formation process of the gate masks 138 may include recessing replacement gate structures 123, filling the resulting recesses with a dielectric material such as silicon nitride, silicon carbonitride, silicon oxynitride, silicon oxycarbonitride, or the like, and performing a planarization process to remove excess portions of the dielectric material over the first ILD 114. The remaining portions of the dielectric material form the gate masks 138.

Next, source/drain contact plugs 119 and gate contact plugs 118 are formed to electrically couple to the source/drain regions 112 and the replacement gate structures 123, respectively. In the illustrated embodiments, the source/drain contact plugs 119 and the gate contact plugs 118 are formed in a self-aligned manner, and fill the spaces between opposing sidewalls of the CESL 116 and spaces between opposing sidewalls of the gate spacers 108, respectively.

In some embodiments, one or more anisotropic etching processes are performed to remove portions of the first ILD 114 and portions of the CESL 116 that are disposed over the source/drain regions 112 to form source/drain contact openings and to expose the source/drain regions 112. Similar, one or more anisotropic etching processes may be performed to remove the gate masks 138 to form the gate contact openings that expose the replacement gate structures 123.

The source/drain contact plugs 119 and the gate contact plugs 118 may be formed by filling the source/drain contact openings and the gate contact openings with an electrically conductive material(s), such as tungsten, although other suitable materials such as aluminum, copper, tungsten nitride, rhuthenium, silver, gold, rhodium, molybdenum, nickel, cobalt, cadmium, zinc, alloys of these, combinations thereof, and the like, may alternatively be utilized. A planarization process, such as CMP, may be performed to remove excess portions of the electrically conducive material(s) that are disposed outside of the source/drain contact openings and the gate contact openings. The number and the location of the source/drain contact plugs 119 and the gate contact plugs 118 illustrated in the figures are illustrative and non-limiting, as skilled artisans readily appreciate.

In the illustrated embodiments, silicide regions 99 are formed on the source/drain regions 112 before the source/drain contact openings are filled to form the source/drain contact plugs 119. In some embodiments, the silicide regions 99 are formed by depositing a metal capable of reacting with semiconductor materials (e.g., silicon, germanium) to form silicide or germanide regions, such as nickel, cobalt, titanium, tantalum, platinum, tungsten, other noble metals, other refractory metals, rare earth metals or their alloys, over the source/drain regions 112, then performing a thermal anneal process to form the silicide regions 99. The un-reacted portions of the deposited metal are then removed, e.g., by an etching process. Although regions 99 are referred to as silicide regions, regions 99 may also be germanide regions, or silicon germanide regions (e.g., regions comprising silicide and germanide).

Next, an etch stop layer (ESL) 134 and a second ILD 135 are formed sequentially over, e.g., the first ILD 114, the replacement gate structures 123, and the gate spacers 108. The ESL 134 may include a dielectric material having a high etching selectivity from the etching of the second ILD 135, such as aluminum oxide, aluminum nitride, silicon oxycarbide, or the like, and may be formed using CVD, ALD, or the like. The second ILD 135 may be formed of PSG, BSG, BPSG, USG, or the like, which may be deposited by any suitable method, such as CVD, flowable CVD, PECVD, or the like.

Next, vias 131 are formed to extend through the second ILD 135 and the ESL 134, and to electrically couple to the source/drain contact plugs 119 and gate contact plugs 118. The vias 131 may be formed by forming via openings that extend through the second ILD 135 and the ESL 134, then filling the via openings with an electrically conductive material(s). The electrically conductive material(s) may be the same as or similar to those used for the source/drain contact plugs 119 or the gate contact plugs 118, thus details are not repeated. In some embodiments, a liner layer (e.g., a diffusion barrier layer) may be formed along sidewalls of the via openings before the electrically conductive material(s) fills the via openings. The liner layer may be titanium, tantalum, titanium nitride, tantalum nitride, or the like, and may be formed using any suitable formation methods, such as CVD, ALD, or the like.

In FIGS. 10A and 10B, the layers of the NSFET device 100 disposed between upper portions of the fins 90 and the second ILD 135 are collectively referred to as the device layer 142 of the NSFET device 100.

Still referring to FIGS. 10A and 10B, next, a front-side interconnect structure 130 is formed on the device layer 142. The front-side interconnect structure 130 includes dielectric layers 136 and layers of conductive features 132 in the dielectric layers 136. The dielectric layers 136 may include a suitable dielectric material, such as silicon oxide, silicon nitride, a low-K dielectric material, combinations therefore, or the like, and may be formed by any suitable formation method, such as CVD, PECVD, ALD, combinations thereof, or the like. The conductive features 132 (e.g., electrically conductive features) may include metal lines and vias, which may be formed using, e.g., damascene processes. The conductive features 132 may include diffusion barriers and a metal-containing material (e.g., copper) over the diffusion barriers. The diffusion barriers (may also be referred to as liner layers) may be, e.g., Ta, Ti, TaN, TiN, or the like. The metal-containing material may be, e.g., Cu, Co, Ru, Mo, or the like. In some embodiments, the topmost conductive features 132 (e.g., the conductive features 132 in a topmost dielectric layer 136T distal from the device layer 142) may include conductive features 132P (e.g., bonding pads, or metal patterns used for bonding) used for bonding with another semiconductor device. Therefore, the conductive features 132P may also be referred to as bonding features or bonding structures.

In the illustrated embodiment, the topmost dielectric layer 136T (may also be referred to as the outermost dielectric layer 136T) of the front-side interconnect structure 130 is formed of a polycrystalline material with a high thermal conductivity (e.g., with a thermal conductivity higher than about 100 W/(m·k)). Examples of the polycrystalline material for the topmost dielectric layer 136T include carbon, ceramic, and composites with polycrystalline structures, such as aluminum nitride, silicon carbide, beryllium oxide, metal nitride, and metal oxide. Examples of the metal material in the metal nitride or metal oxide include aluminum, titanium, and tantalum. In some embodiments, other dielectric layers 136 of the front-side interconnect structure 130 are formed of a different dielectric material (e.g., a non-polycrystalline dielectric material such as silicon oxide) than the topmost dielectric layer 136T.

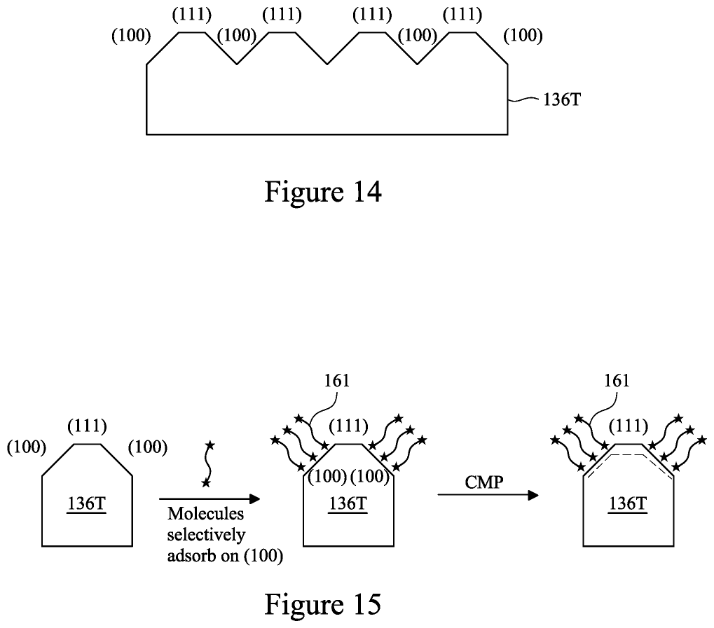

Polycrystalline materials with high thermal conductivity may be advantageously used as bonding materials at bonding interfaces of semiconductor devices to increase the efficiency of thermal dissipation. In addition, polycrystalline materials may also be used as heat sinks or heat dissipators in semiconductor devices. The surface of the as-deposited polycrystalline material is typically not flat, and a planarization process, such as CMP, is often performed to planarize the surface of the as-deposited polycrystalline material, in some embodiments. FIG. 14 illustrates the surface of a polycrystalline material, and FIGS. 15-17 illustrate various example methods for planarizing the polycrystalline material.

Referring to FIG. 14, which illustrates a zoomed-in view of a portion 160 of the topmost dielectric layer 136T in FIG. 10A. The upper surface of the topmost dielectric layer 136T (which is a polycrystalline material) in FIG. 14 corresponds to the upper surface of the topmost dielectric layer 136T distal from the device layer 142 in FIG. 10A. For ease of discussion, the topmost dielectric layer 136T is also referred to as polycrystalline material 136T herein.

As illustrated in FIG. 14, the upper surface of the polycrystalline material 136T has different facets extending along different crystal planes, such as facets along (111) direction and along (100) direction. For ease of discussion, facets along (111) direction may also be referred to as facets (111), and facets along the (100) direction may also be referred to as facets (100). In the example of FIG. 14, the top horizontal facets of the polycrystalline material 136T are facets (111), and the sloped facets are facets (100). The facets along different crystal planes have different lattice densities, which result in different hardnesses of the different facets. The different hardnesses in turn result in different removal rates of the polycrystalline material 136T at different facets in a subsequent planarization process (e.g., CMP). Generally, hard facets (e.g., with higher lattice densities) have lower removal rates than soft facets (e.g., with lower lattice densities). In the example of FIG. 14, the facets (111) are harder than the facets (100), thus the facets (111) may also be referred to as hard facets and the facets (100) may also be referred to as soft facets. Therefore, if a CMP process is performed to planarize the polycrystalline material 136T in FIG. 14, the polycrystalline material at the hard facets (e.g., facets (111)) is removed at a first removal rate, and the polycrystalline material at the soft facets (e.g., facets (100)) is removed at a second removal rate higher than the first removal rate. In the discussion herein, the removal rate (e.g., the first removal rate) of the polycrystalline material at a facet (e.g., facet (111)) refers to the rate at which the facet is recessed along a direction (e.g., vertical direction in FIG. 14) perpendicular to that facet during the CMP process.

In the example of FIG. 14, the slower removal rate of the polycrystalline material at the facets (111) (or equivalently, the faster removal rate of the polycrystalline material at the facets (100)) poses a challenge for the CMP process. For example, if the facets (100) are removed at a faster removal rate than the facets (111) during the CMP process, the peaks and valleys in the surface of the polycrystalline material 136T may become more prominent after the CMP process, thus beating the purpose of the CMP process. Therefore, if the facets (111) and (100) are left untreated, the CMP process may not be successful in increasing the planarity of the surface of the polycrystalline material 136T. Various methods for treating the different facets of the polycrystalline material 136T to achieve increased planarity for the surface of the polycrystalline material 136T after the CMP process are disclosed herein with reference to FIG. 15-17.

FIG. 15 illustrates a method where a removal rate modification layer 161 (may also be referred to as a surface modification layer, or an etch rate modification layer) is selectively formed on soft facets (e.g., facets (100)) to decrease the removal rate of the polycrystalline material at the soft facets. A portion of the polycrystalline material 136T before the removal rate modification layer is formed is illustrated on the left-hand side of FIG. 15. Next, as illustrated in the middle portion of FIG. 15, molecules 161 of a suitable chemical are selectively absorbed on the facets (100) to form the removal rate modification layer 161 (e.g., one or more layers of the molecules 161).

In some embodiments, the different facets of the polycrystalline material have different physical and/or chemical properties, such as different surface reactivities, different hydroxyl densities, different hydrophilicities, different coulombic interactions, and so on. These different physical and/or chemical properties may interact with molecules of certain chemicals differently, thus allowing for selective absorption of the molecules on certain facets of the polycrystalline material. Example chemicals whose molecules may be selectively adsorbed on facets of a polycrystalline material include silane, carbonic acid, phosphate, carbonate, sulfonate, amine, and amide. In some embodiments, the chemical is added in the CMP slurry used in the CMP process for selective adsorption of the molecules 161 on the facets of the polycrystalline material. In other embodiments, the chemical is applied on the surfaces of the polycrystalline material for selective adsorption of the molecules 161 before the CMP process is performed.

As illustrated in the right-hand side of FIG. 15, during the CMP process, the removal rate modification layer 161 covers the facets (100) and acts as a barrier to the CMP process, thus reducing the removal rate of the polycrystalline material 136T at the facets (100). The CMP process may remove portions of the removal rate modification layer eventually. After the CMP process is finished, the (remaining portions of) removal rate modification layer 161 is removed by a suitable method, such as a wet etch or dry etch. The dashed lines in FIG. 15 illustrate the recessed facets of the polycrystalline material after the CMP process is finished. In the example of FIG. 15, due to the removal rate modification layer 161 protecting the soft facets (e.g., facets (100)), the facets (100) are recessed less than the hard facets (e.g., facets (111)) after the CMP process is finished, thus reducing the vertical offsets between the peaks and valleys in the surface of the polycrystalline material 136T and increasing the planarity of the surface of the polycrystalline material 136T.

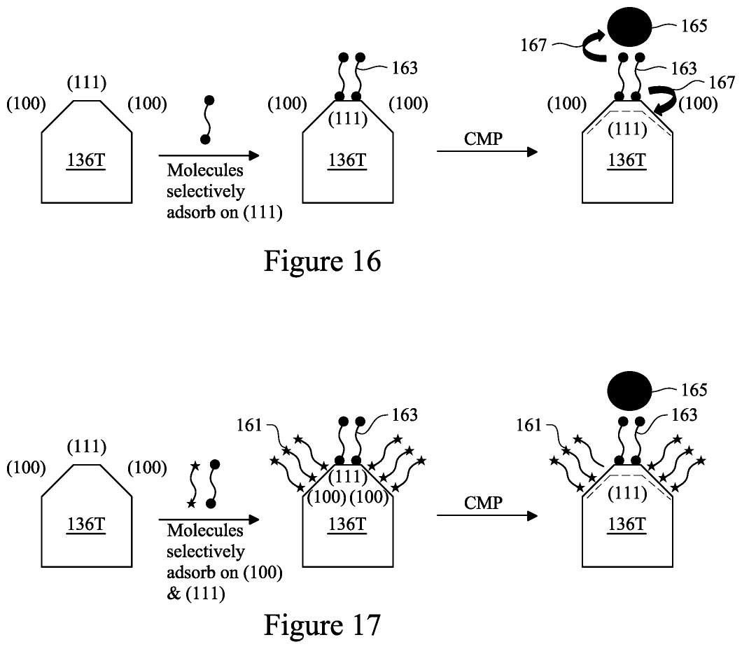

FIG. 16 illustrates a method where a removal rate modification layer 163 is selectively formed on hard facets (e.g., facets (111)) to increase the removal rate of the polycrystalline material at the hard facets. A portion of the polycrystalline material 136T before the removal rate modification layer is formed is illustrated on the left-hand side of FIG. 16. Next, as illustrated in the middle portion of FIG. 16, molecules 163 of a suitable chemical are selectively absorbed on the facets (111) to form the removal rate modification layer 163 (e.g., one or more layers of the molecules 163). The chemical may be added in the CMP slurry for selective adsorption of the molecules 163, or may be applied to the surfaces of the polycrystalline material 136T for selective adsorption of the molecules 163 before the CMP process is performed.

In some embodiments, abrasive particles 165 contained in the CMP slurry (also referred to as slurry) and the polycrystalline material 136T carry the same type of electrical charge (e.g., same positive electrical charge, or same negative electrical charge), and the molecules 163 carry a different (e.g., an opposite) type of electrical charge. The molecules 163 carrying electrical charges may also be referred to as ions. Due to attraction between opposite types of electrical charges, the selectively adsorbed molecules 163 on the facets (111) enhance the interaction between the abrasive particles 165 in the CMP slurry and the facets (111), thus increasing the removal rate of the polycrystalline material at the facets (111), as illustrated by the right-hand side of the FIG. 16. In an embodiment, the abrasive particles 165 in the CMP slurry are diamond abrasive particles carrying negative electrical charges, the polycrystalline material 136T is a diamond film carrying negative electrical charges, and the molecules 163 are cations carrying positive electrical charges, such as dications of arginine. As another example, both the abrasive particles 165 and the polycrystalline material 136T carry positive electrical charges, and the molecules 163 are anions carrying negative electrical charges.

In some embodiments, the molecules 163 are dianions that have two negative charges (e.g., having a net charge of −2). In some embodiments, the molecules 163 are dications that have two positive charges (e.g., having a net charge of +2). Besides arginine, chemicals with di-charges that may be used to form the removal rate modification layer in FIG. 16 include polyacrylic acid, polyethyleneimine, cetyltrimethylammonium bromide, lauryl betaine, cocamidopropyl betaine, polyamidoamine dendrimers, chitosan, and sodium dodecyl sulfate.

In some embodiments, the molecules 163 have three negative charges (e.g., having a net charge of −3), and may be provided by chemicals having tri-carboxylate groups, such as citric acid, aconitic acid, trimesic acid, or 1,2,3-propanetricarboxylic acid. In some embodiments, the molecules 163 have three positive charges (e.g., having a net charge of +3), and may be provided by chemicals having tri-amine groups, such as diethylenetriamine, triethylenetetramine, or bis(hexamethylene)triamine.

The arrows 167 in FIG. 16 illustrate the electrical attraction between the molecules 163 and the abrasive particles 165, and between the molecules 163 and the facets (111) of the polycrystalline material 136T. The dashed lines in FIG. 16 illustrate the recessed facets of the polycrystalline material 136T after the CMP process is finished. After the CMP process is finished, the (remaining portions of) removal rate modification layer 163 is removed by a suitable method, such as a wet etch or dry etch. In the example of FIG. 16, due to the removal rate modification layer 163 enhancing (e.g., increasing) the removal rate of the polycrystalline material at the facets (111), the facets (111) are recessed more than the facets (100) after the CMP process is finished, thus reducing the vertical offsets between the peaks and valleys in the surface of the polycrystalline material 136T and increasing the planarity of the surface of the polycrystalline material 136T.

Note that in the example of FIG. 15, the removal rate modification layer 161 (e.g., one or more layers of molecules 161) reduces the removal rate of the polycrystalline material at the soft facets (e.g., facets (100)), which soft facets have a faster removal rate than the hard facets (e.g., facets (111)). In the example of FIG. 16, the removal rate modification layer 163 (e.g., one or more layers of molecules 163) increases the removal rate of the polycrystalline material at the hard facets (e.g., facets (111)), which hard facets have a slower removal rate than the soft facets (e.g., facets (100)). Therefore, the effect of the removal rate modification layers 161 and 163 in FIGS. 15 and 16 may be referred to as reducing the difference (e.g., the absolute value of the difference) between the removal rate of the polycrystalline material at the soft facets and the removal rate of the polycrystalline material at the hard facets, or as compensating the difference between the removal rate of the polycrystalline material at the soft facets and the removal rate of the polycrystalline material at the hard facets, in some embodiments.

FIG. 17 illustrates a method where a first removal rate modification layer 161 (e.g., one or more layers of molecules 161) is formed on soft facets (e.g., facets (100)) to decrease the removal rate of the polycrystalline material at the soft facets, and a second removal rate modification layer 163 (e.g., one or more layers of molecules 163) is formed on hard facets (e.g., facets (111)) to increase the removal rate of the polycrystalline material at the hard facets. Skilled artisans will readily appreciate that the method of FIG. 17 is a combination of the methods disclosed in FIGS. 15 and 16. The details regarding the molecules 161 and 163 in FIG. 17 and their formation methods are the same as or similar to those discussed above, thus not repeated.

Modifications and variations of the disclosed methods are possible and are fully intended to be included within the scope of the present disclosure. For example, in the embodiment of FIG. 15, the selective absorption of molecules 161 results in the removal rate modification layer being formed on the facets (100), and the removal rate modification layer is not formed on the facets (111). This is, of course, merely a non-limiting example. An embodiment where the selective absorption of molecules 161 results in a thicker removal rate modification layer on the facets (100) and a thinner removal rate modification layer on the facets (111) is contemplated and is within the scope of the present disclosure. The thicker removal rate modification layer on the facets (100) may include, e.g., more layers of the molecules 161 than the thinner removal rate modification layer on the facets (111). Similarly, the selectively adsorption of molecules 163 may result in a thicker removal rate modification layer (e.g., with more layers of the molecules 163) on the facets (111) and a thinner removal rate modification layer on the facets (100).

Referring back to FIGS. 10A and 10B, after the topmost dielectric layer 136T is planarized, the conductive features 132P are formed in the topmost dielectric layer 136T using a suitable formation method, such as damascene. In the illustrated embodiments, the conductive features 132P are exposed at the outermost surface of the front-side interconnect structure 130 distal from the device layer 142. For example, top surfaces 132PU of the conductive features 132P are level (e.g., flush) with the upper surface of the topmost dielectric layer 136T of the front-side interconnect structure 130.

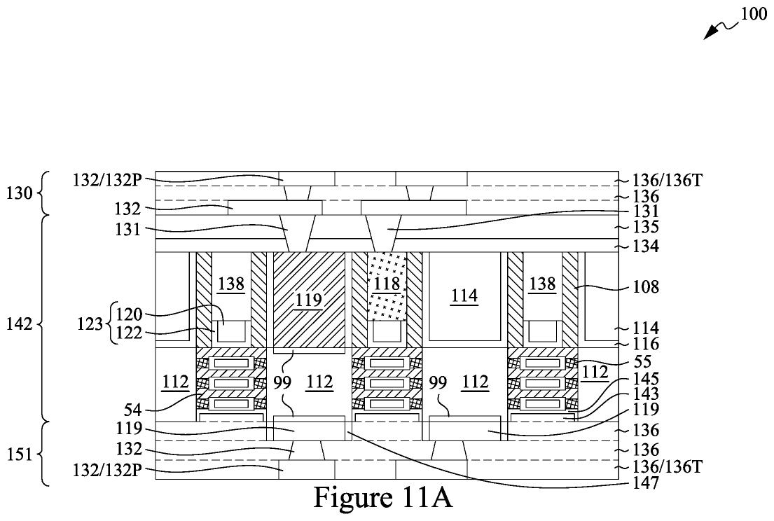

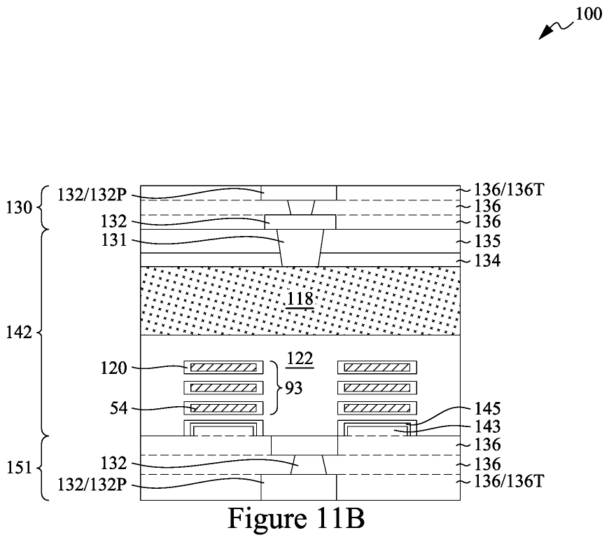

Next, in FIGS. 11A and 11B, a backside thinning process is performed, and a backside interconnect structure 151 is formed at an opposing side of the device layer 142 from the front-side interconnect structure 130. Details are discussed hereinafter.

In some embodiments, a thinning process is performed from the backside of the substrate 50 to thin the substrate 50. The thinning process may be a grinding process, a CMP process, an etching process, combinations thereof, or the like. The thinning process may remove the substrate 50, the STI regions 96, and lower portions of the fins 90. In some embodiments, the thinning process is stopped when the source/drain regions 112 are exposed. Next, remaining portions of the fins 90 (e.g., top portions contacting the replacement gate structures 123) are removed (e.g., by a selective etching process) to form recesses between, e.g., neighboring pairs of source/drain regions 112. An ESL 145 is formed to line sidewalls and bottoms of the recesses. The ESL 145 may be formed using a same or similar material and formation method as the CESL 116, thus details are not repeated. Next, a dielectric material 143 is formed on the ESL 145 and fills the recesses. The dielectric material 143 may be, e.g., SiO, SiN, or a low-K dielectric material formed using any suitable formation method. A planarization process, such as CMP, may be performed next to achieve a coplanar lower surface between the source/drain regions 112, the ESL 145, and the dielectric material 143. After the ESL 145 and the dielectric material 143 are formed, the layers of the NSFET device 100 disposed between the second ILD 135 and the lower surfaces of the source/drain regions 112 are collectively referred to as the device layer 142 of the NSFET device 100.

Next, the backside interconnect structures 151, which includes dielectric layers 136 and conductive features 132, are formed on the backside of the device layer 142. The backside interconnect structures 151 may include source/drain contact plugs 119 formed in the innermost dielectric layer 136 contacting the dielectric material 143. Silicide regions 99 are formed at the lower surfaces of the source/drain regions 112 before the source/drain contact plugs 119 are formed, in the illustrated embodiments. FIGS. 11A and 11B further illustrate a liner layer 147 (e.g., a diffusion barrier layer) around the source/drain contact plugs 119. The liner layer 147 may be formed of a suitable material such as titanium, tantalum, titanium nitride, tantalum nitride, or the like, and may be formed using any suitable formation methods, such as CVD, ALD, or the like.

The backside interconnect structures 151 also includes conductive features 132P (e.g., bonding pads) embedded in an outermost dielectric layer 136T distal from the device layer 142. In some embodiments, the outermost dielectric layer 136T of the backside interconnect structures 151 is formed of a polycrystalline material same as or similar to the topmost dielectric layer 136T of the front-side interconnect structure 130. The outermost dielectric layer 136T of the backside interconnect structures 151 is then planarized using a CMP process, and removal rate modification layer(s) same as or similar to those discussed above in FIGS. 15-17 is used to achieve a substantially flat surface after the CMP process, in some embodiments.

Next, in FIGS. 12A and 12B, the NSFET device 100 is bonded to an NSFET device 200 to form a CFET device 300. The NSFET device 200 is similar to the NSFET device 100 and may be formed using a same or similar formation method. The source/drain regions 124 of the NSFET device 200 have a different conductivity type (e.g., n-type or p-type) from the source/drain regions 112 of the NSFET device 100, in some embodiments. For example, the source/drain regions 112 of the NSFET device 100 may have a first doping type (e.g., doped with a dopant of a first conductivity type, such as n-type), and the source/drain regions 124 of the NSFET device 200 may have a second doping type (e.g., doped with a dopant of a second conductivity type, such as p-type) different from the first doping type. In other words, one of the NSFET devices 100 and 200 may be formed using n-type NSFETs, and the other one of the NSFET devices 100 and 200 may be formed using p-type NSFETs. In other embodiments, the source/drain regions 112 of the NSFET device 100 and the source/drain regions 124 of the NSFET device 200 have a same doping type (e.g., both are doped with n-type or p-type dopant).

In the example of FIGS. 12A and 12B, the front-side interconnect structure 130 of the NSFET device 200 is bonded to the front-side interconnect structure 130 of the NSFET device 100 to form the CFET device 300. This bonding scheme is also referred to as front-side to front-side bonding.

In FIGS. 12A and 12B, the topmost dielectric layer 136T of the front-side interconnect structure 130 of the NSFET device 100 is bonded with the topmost dielectric layer 136T of the front-side interconnect structure 130 of the NSFET device 200 through dielectric-to-dielectric bonding (also referred to as direct dielectric-to-dielectric bonding), and the conductive features 132P of the front-side interconnect structure 130 of the NSFET device 100 are bonded with respective conductive features 132P of the front-side interconnect structure 130 of the NSFET device 200 through metal-to-metal bonding (also referred to as direct metal-to-metal bonding).

Dielectric-to-dielectric bonding and metal-to-metal bonding are bonding techniques that could be used in a direct bonding process to bond two semiconductor devices together without using an intermediate layer (e.g., solder or an adhesive layer). The direct bonding process uses dielectric-to-dielectric bonding and/or metal-to-metal bonding to achieve a robust and reliable connection at the interface of two devices. Metal-to-metal bonding involves aligning and applying sufficient pressure on metal surfaces, such as copper or aluminum surfaces, often accompanied by thermal treatment to facilitate atomic diffusion and interfacial adhesion without an intermediate layer (e.g., solder). Dielectric-to-dielectric bonding uses surfaces such as silicon dioxide or other insulating materials, which, when aligned under appropriate conditions (e.g., at an elevated temperature and/or with pressure applied at the surfaces), form bonds through forces such as Van der Waals force or covalent interactions. The direct bonding process is instrumental in creating high-density, low-resistance connections while reducing or minimizing thermal budgets.

Still referring to FIGS. 12A and 12B, a heat sink 149 (may also be referred to as a heat dissipator), which is optional, is formed on the outermost dielectric layer 136T of the backside interconnect structure 151 of the NSFET device 200. In some embodiments, the heat sink 149 is a layer of a polycrystalline material with high thermal conductivity, and may be formed of a same or similar material using the same or similar formation method as the polycrystalline material 136T. In some embodiments, the heat sink 149 is omitted. Similarly, an optional heat sink 149 may be formed on the outermost dielectric layer 136T of the backside interconnect structure 151 of the NSFET device 100. In some embodiments where the heat sink 149 (e.g., a polycrystalline material) is formed, the outermost dielectric layer 136T of the backside interconnect structure 151 contacting the heat sink 149 may be formed of a same dielectric material (e.g., a non-polycrystalline dielectric material such as silicon oxide) as the other dielectric layers 136 of the backside interconnect structure 151. In some embodiments, both the heat sink 149 and the dielectric layer 136T contacting the heat sink 149 are formed of a polycrystalline material with high thermal conductivity.

In some embodiments, multiple NSFET devices 100 are formed on a first wafer (e.g., a substrate 50), and multiple NSFET devices 200 are formed on a second wafer (e.g., another substrate 50). After the front-side interconnect structures 130 on both wafers are bonded together, a wafer-on-wafer structure is formed that comprises multiple CFET devices 300. Next, a dicing process is performed along dicing regions indicated by the dashed lines 150 in FIGS. 12A and 12B to separate the wafer-on-wafer structure into individual (e.g., separate) CFET devices 300, where each of the CFET devices 300 includes an NSFET device 100 and an NSFET device 200 stacked vertically (e.g., bonded together). In some embodiments, the NSFET devices 100 and 200 in the CFET device 300 are of different conductivity types. In other embodiments, the NSFET devices 100 and 200 in the CFET device 300 are of the same conductivity type.

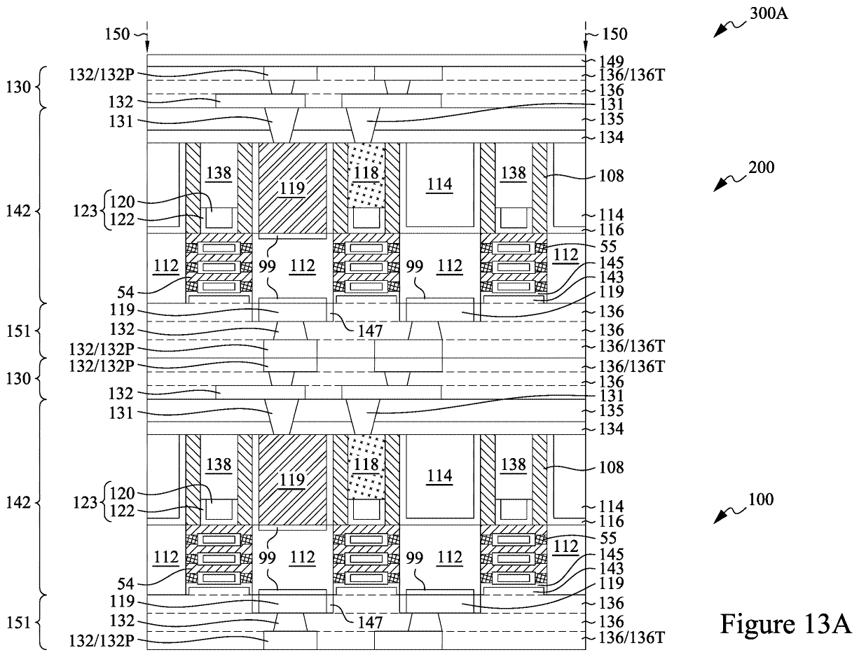

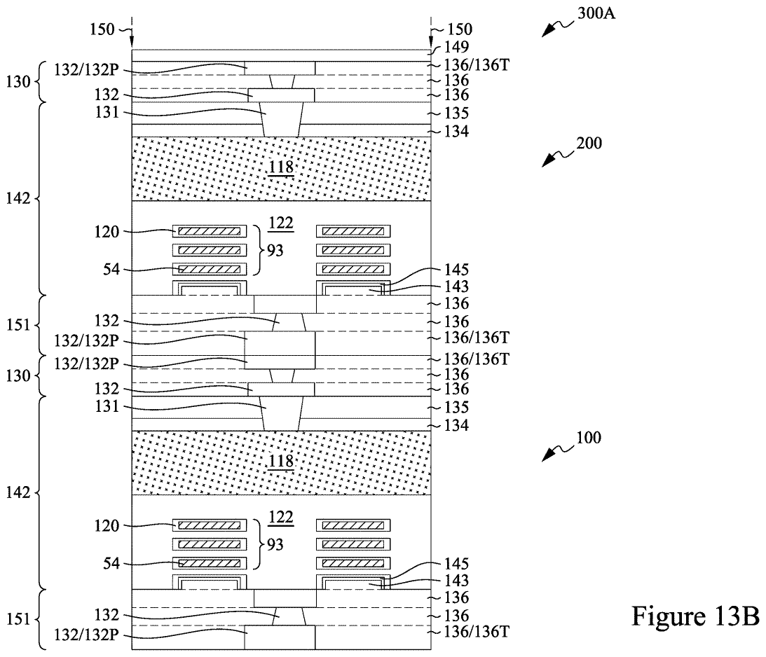

FIGS. 13A and 13B illustrate cross-sectional views of a CFET device 300A, in accordance with another embodiment. The CFET device 300A is similar to the CFET device 300, but with the front-side interconnect structure 130 of the NSFET device 100 bonded to the backside interconnect structure 151 of the NSFET device 200. This bonding scheme is also referred to as front-side to backside bonding. Similar to the CFET device 300, dielectric-to-dielectric bonding and metal-to-metal bonding are used to bond the NSFET device 100 with the NSFET device 200 without using an intermediate layer.

In the example of FIGS. 13A and 13B, an optional heat sink 149 is formed on the topmost dielectric layer 136T of the front-side interconnect structure 130 of the NSFET device 200. Similarly, an optional heat sink 149 may be formed on the outermost dielectric layer 136T of the backside interconnect structure 151 of the NSFET device 100. In some embodiments where the optional heat sink 149 is formed, the dielectric layer 136T contacting the heat sink 149 may be formed of a same dielectric material (e.g., a non-polycrystalline dielectric material such as silicon oxide) as other dielectric layers 136 of the front-side (or backside) interconnect structure. In some embodiments, both the heat sink 149 and the dielectric layer 136T contacting the heat sink 149 are formed of a polycrystalline material with high thermal conductivity.

In some embodiments, a dicing process may be performed next along the dicing regions indicated by the dashed lines 150 in FIGS. 13A and 13B, in order to separate the plurality of CFET devices 300A formed in a wafer-on-wafer structure into a plurality of individual (e.g., separate) CFET devices 300A.

Advantages are achieved by the disclosed embodiments. For example, by using the polycrystalline material with high thermal conductivity at the bonding interface of two devices, the efficiency of heat dissipation is improved, and enhanced thermal management for advanced devices is achieved. The disclosed removal rate modification layers, formed through facet-dependent adsorption, can selectively enhance (e.g., increase) or decrease the polishing efficiency of the CMP process at different facets of the polycrystalline material to achieve improved planarity for the surface of the polycrystalline material. The disclosed methods for facet-dependent adsorption are versatile across different types of materials, and can be easily integrated into existing process flow for cost-effective implementation.

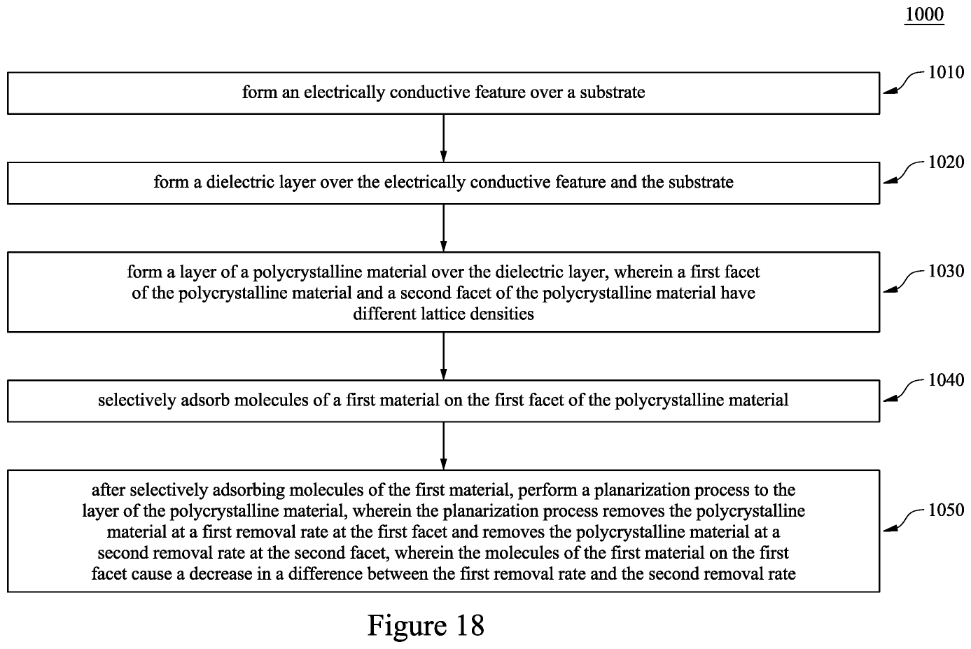

FIG. 18 illustrates a flow chart of a method 1000 of forming a semiconductor device, in accordance with some embodiments. It should be understood that the embodiment method shown in FIG. 18 is merely an example of many possible embodiment methods. One of ordinary skill in the art would recognize many variations, alternatives, and modifications. For example, various steps as illustrated in FIG. 18 may be added, removed, replaced, rearranged, or repeated.

Referring to FIG. 18, at block 1010, an electrically conductive feature is formed over a substrate. At block 1020, a dielectric layer is formed over the electrically conductive feature and the substrate. At block 1030, a layer of a polycrystalline material is formed over the dielectric layer, wherein a first facet of the polycrystalline material and a second facet of the polycrystalline material have different lattice densities. At block 1040, molecules of a first material are selectively adsorbed on the first facet of the polycrystalline material. At block 1050, after selectively adsorbing molecules of the first material, a planarization process is performed to the layer of the polycrystalline material, wherein the planarization process removes the polycrystalline material at a first removal rate at the first facet and removes the polycrystalline material at a second removal rate at the second facet, wherein the molecules of the first material on the first facet cause a decrease in a difference between the first removal rate and the second removal rate.

In an embodiment, a method of forming a semiconductor device includes: forming a device layer over a first substrate, wherein the device layer comprises a transistor, wherein the transistor comprises a fin protruding above the first substrate, channel regions over the fin, a gate structure around the channel regions, and source/drain region over the fin and on opposing sides of the gate structure; and forming an interconnect structure at a first side of the device layer and electrically coupled to the transistor, wherein the interconnect structure comprises first dielectric layers and electrically conductive features embedded in the first dielectric layers, wherein forming the interconnect structure comprises: forming an outermost dielectric layer of the interconnect structure distal from the device layer using a polycrystalline material, wherein a first facet of the polycrystalline material and a second facet of the polycrystalline material have different lattice densities; selectively adsorbing molecules of a first material on the first facet of the polycrystalline material; and after selectively adsorbing molecules of the first material, performing a planarization process to the polycrystalline material, wherein the molecules of the first material reduce a different between a first removal rate of the polycrystalline material at the first facet and a second removal rate of the polycrystalline material at the second facet during the planarization process. The method further includes, after forming the interconnect structure, bonding the outermost dielectric layer of the interconnect structure to a second dielectric layer formed over a second substrate. In an embodiment, the first facet has a higher lattice density than the second facet, wherein the molecules of the first material cause an increase in the first removal rate of the polycrystalline material at the first facet during the planarization process. In an embodiment, the planarization process comprises a chemical mechanical planarization (CMP) process performed using a slurry containing abrasive particles, wherein the abrasive particles and the polycrystalline material carry a first type of electrical charge, wherein the molecules of the first material carry a second type of electrical charge different from the first type of electrical charge. In an embodiment, the abrasive particles and the polycrystalline material carry negative electrical charges, and the molecules of the first material are cations. In an embodiment, the abrasive particles and the polycrystalline material carry positive electrical charges, and the molecules of the first material are anions. In an embodiment, the first facet has a lower lattice density than the second facet, wherein the molecules of the first material cause a decrease in the first removal rate of the polycrystalline material at the first facet during the planarization process. In an embodiment, the molecules of the first material are molecules of silane, molecules of carbonic acid, molecules of a phosphate, molecules of a carbonate, molecules of a sulfonate, molecules of an amine, or molecules of an amide. In an embodiment, the polycrystalline material has a higher thermal conductivity than silicon. In an embodiment, forming the interconnect structure further comprises selectively absorbing molecules of a second material on the second facet of the polycrystalline material. In an embodiment, the first facet has a higher lattice density than the second facet, wherein the molecules of the first material cause an increase in the first removal rate of the polycrystalline material at the first facet during the planarization process, wherein the molecules of the second material cause a decrease in the second removal rate of the polycrystalline material at the second facet during the planarization process. In an embodiment, bonding the outermost dielectric layer comprises bonding the outermost dielectric layer of the interconnect structure to the second dielectric layer through dielectric-to-dielectric bonding.

In an embodiment, a method of forming a semiconductor device includes: forming a device layer over a first substrate, wherein the device layer comprises a transistor; forming a first dielectric layer over the first substrate and the transistor; forming an electrically conductive feature in the first dielectric layer, wherein the electrically conductive feature is electrically coupled to the transistor; forming a layer of a polycrystalline material over the first dielectric layer, wherein a first facet of the polycrystalline material and a second facet of the polycrystalline material have different lattice densities; selectively forming a removal rate modification layer on the first facet of the polycrystalline material by selective adsorption of molecules of a first material on the first facet; and after selectively forming the removal rate modification layer, performing a planarization process to the polycrystalline material, wherein the planarization process removes the polycrystalline material at a first removal rate at the first facet and removes the polycrystalline material at a second removal rate at the second facet, wherein the removal rate modification layer causes a decrease in a difference between the first removal rate and the second removal rate. In an embodiment, the method further comprises, after performing the planarization process, bonding the layer of the polycrystalline material to a second dielectric layer formed over a second substrate through dielectric-to-dielectric bonding. In an embodiment, the method further comprises, after performing the planarization process and before bonding the layer of the polycrystalline material, forming a first bonding feature in the layer of the polycrystalline material, wherein the method further comprises bonding the first bonding feature to a second bonding feature embedded in the second dielectric layer through metal-to-metal bonding. In an embodiment, the first facet has a lower lattice density than the second facet, wherein the removal rate modification layer causes a decrease in the first removal rate. In an embodiment, the first facet has a higher lattice density than the second facet, wherein the removal rate modification layer causes an increase in the first removal rate.

In an embodiment, a method of forming a semiconductor device includes: forming an electrically conductive feature over a substrate; forming a dielectric layer over the electrically conductive feature and the substrate; forming a layer of a polycrystalline material over the dielectric layer, wherein a first facet of the polycrystalline material and a second facet of the polycrystalline material have different lattice densities; selectively adsorbing molecules of a first material on the first facet of the polycrystalline material; and after selectively adsorbing molecules of the first material, performing a planarization process to the layer of the polycrystalline material, wherein the planarization process removes the polycrystalline material at a first removal rate at the first facet and removes the polycrystalline material at a second removal rate at the second facet, wherein the molecules of the first material on the first facet cause a decrease in a difference between the first removal rate and the second removal rate. In an embodiment, the first facet has a lower lattice density than the second facet, wherein the molecules of the first material on the first facet cause a decrease in the first removal rate. In an embodiment, the first facet has a higher lattice density than the second facet, wherein the molecules of the first material on the first facet cause an increase in the first removal rate. In an embodiment, wherein the first facet has a lower lattice density than the second facet, wherein the method further comprises selectively adsorbing molecules of a second material on the second facet of the polycrystalline material, wherein the molecules of the first material on the first facet cause a decrease in the first removal rate, and wherein the molecules of the second material on the second facet cause an increase in the second removal rate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a device layer over a substrate, the device layer comprising an electronic component;
forming an interconnect structure over the device layer, wherein the interconnect structure comprises first dielectric layers and electrically conductive features embedded in the first dielectric layers, wherein an uppermost dielectric layer of the first dielectric layers distal from the substrate is formed of a polycrystalline material, wherein a first facet of the polycrystalline material has a first lattice density, and a second facet of the polycrystalline material has a second lattice density different from the first lattice density;
planarizing the uppermost dielectric layer, comprising:
selectively adsorbing molecules of a first chemical onto the first facet of the polycrystalline material to form a first removal rate modification layer; and
after selectively adsorbing the molecules of the first chemical, performing a planarization process on the polycrystalline material, wherein the first removal rate modification layer reduces a difference between a first removal rate of the polycrystalline material at the first facet and a second removal rate of the polycrystalline material at the second facet during the planarization process; and
after planarizing the uppermost dielectric layer, bonding the uppermost dielectric layer to a second dielectric layer.

2. The method of claim 1, wherein selectively adsorbing the molecules of the first chemical onto the first facet comprises applying the first chemical to a surface of the polycrystalline material.

3. The method of claim 1, wherein the planarization process comprises a chemical mechanical planarization (CMP) process performed using a slurry, wherein selectively adsorbing the molecules of the first chemical onto the first facet comprises adding the first chemical to the slurry.

4. The method of claim 1, wherein other dielectric layers of the first dielectric layers other than the uppermost dielectric layer are formed of a non-polycrystalline material.

5. The method of claim 4, wherein the non-polycrystalline material has a lower thermal conductivity than the polycrystalline material.

6. The method of claim 1, wherein the first lattice density is lower than the second lattice density, wherein the first removal rate modification layer decreases the first removal rate of the polycrystalline material at the first facet during the planarization process.

7. The method of claim 6, wherein the first chemical is a silane, a carbonic acid, a phosphate, a carbonate, a sulfonate, an amine, or an amide.

8. The method of claim 1, wherein the first lattice density is higher than the second lattice density, wherein the first removal rate modification layer increases the first removal rate of the polycrystalline material at the first facet during the planarization process.

9. The method of claim 8, wherein the planarization process comprises a chemical mechanical planarization (CMP) process performed using a slurry comprising abrasive particles, wherein the abrasive particles and the polycrystalline material carry electrical charges of a first polarity, and the molecules of the first chemical carry electrical charges of a second polarity opposite the first polarity.

10. The method of claim 9, wherein the abrasive particles and the polycrystalline material carry positive electrical charges, and the molecules of the first chemical are anions.

11. The method of claim 9, wherein the abrasive particles and the polycrystalline material carry negative electrical charges, and the molecules of the first chemical are cations.

12. The method of claim 8, wherein planarizing the uppermost dielectric layer further comprises selectively adsorbing molecules of a second chemical onto the second facet of the polycrystalline material to form a second removal rate modification layer, wherein the second removal rate modification layer causes a decrease in the second removal rate of the polycrystalline material at the second facet during the planarization process.

13. A method of forming a semiconductor device, the method comprising:
forming a device layer comprising an electronic component;
forming a first dielectric layer over the device layer;
forming a first electrically conductive feature in the first dielectric layer, wherein the first electrically conductive feature is electrically coupled to the electronic component;
forming a bonding layer over the first dielectric layer, wherein the bonding layer is formed of a polycrystalline material, wherein a first facet of the polycrystalline material and a second facet of the polycrystalline material have different lattice densities;
selectively forming a removal rate modification layer on the first facet of the polycrystalline material by selectively adsorbing molecules of a first material on the first facet; and
after selectively forming the removal rate modification layer, planarizing the bonding layer using a planarization process, wherein the planarization process removes the polycrystalline material at a first removal rate at the first facet and removes the polycrystalline material at a second removal rate at the second facet, wherein the removal rate modification layer reduces a discrepancy between the first removal rate and the second removal rate.

14. The method of claim 13, further comprising, after planarizing the bonding layer, bonding the bonding layer to a pre-formed second dielectric layer through dielectric-to-dielectric bonding.

15. The method of claim 13, wherein the first facet has a lower lattice density than the second facet, wherein the removal rate modification layer decreases the first removal rate.

16. The method of claim 13, wherein the first facet has a higher lattice density than the second facet, wherein the removal rate modification layer increases the first removal rate.

17. A method of forming a semiconductor device, the method comprising:
forming an electrically conductive feature in a dielectric layer;
forming a polycrystalline material over the dielectric layer, wherein a first facet of the polycrystalline material and a second facet of the polycrystalline material have different lattice densities;
selectively adsorbing molecules of a first material on the first facet of the polycrystalline material; and
after selectively adsorbing molecules of the first material, performing a planarization process on the polycrystalline material, wherein the planarization process removes the polycrystalline material at a first removal rate at the first facet and removes the polycrystalline material at a second removal rate at the second facet, wherein the molecules of the first material on the first facet cause a decrease in a difference between the first removal rate and the second removal rate.

18. The method of claim 17, wherein a first lattice density of the first facet is lower than a second lattice density of the second facet, wherein the molecules of the first material on the first facet cause a decrease in the first removal rate.

19. The method of claim 17, wherein a first lattice density of the first facet is higher than a second lattice density of the second facet, wherein the molecules of the first material on the first facet cause an increase in the first removal rate.

20. The method of claim 17, wherein a first lattice density of the first facet is higher than a second lattice density of the second facet, wherein the method further comprises selectively adsorbing molecules of a second material on the second facet of the polycrystalline material, wherein the molecules of the first material on the first facet cause an increase in the first removal rate, and wherein the molecules of the second material on the second facet cause a decrease in the second removal rate.
